(19) United States
(12) Patent Application Publication
(10) Pub. No.: US 2024/0172411 A1
(43) Pub. Date: May 23, 2024

(54) TRANSISTOR ARRAY AND METHOD FOR MANUFACTURING SAME, SEMICONDUCTOR DEVICE AND METHOD FOR MANUFACTURING SAME

(71) Applicant: ICLEAGUE TECHNOLOGY CO., LTD., Jiaxing, Zhejiang (CN)

(72) Inventors: Wenyu HUA, Jiaxing (CN); Zhongwei LUO, Jiaxing (CN); Zhi ZHANG, Jiaxing (CN)

(73) Assignee: ICLEAGUE TECHNOLOGY CO., LTD., Jiaxing, Zhejiang (CN)

(21) Appl. No.: 17/784,791

(22) PCT Filed: Aug. 6, 2021
(86) PCT No.: PCT/CN2021/111343

§ 371 Date: Jun. 13, 2022

(30) Foreign Application Priority Data
Jul. 2, 2021 (CN) 202110750542.0

(51) Int. Cl. H10B 12/00; H10B 53/30; H10B 63/00; H10B 63/10

(52) U.S. Cl. CPC H10B 12/05; H10B 12/33; H10B 53/30; H10B 63/10; H10B 63/34

(57) ABSTRACT

The disclosure provides a transistor array and a method for manufacturing the same, and a semiconductor device and a method for manufacturing the same. The method for manufacturing a transistor array may include the following operations. A wafer is provided. The wafer is partially etched from a first surface of the wafer along a first direction, to form a grid-like etched trench and a transistor pillar array, here the transistor pillar array includes multiple transistor pillars arranged in an array, each of the multiple transistor pillars has a first preset thickness smaller than an initial thickness of the wafer. An insulating material is deposited in the grid-like etched trench to form an insulating layer surrounding each of the multiple transistor pillars. The insulating layer is etched to expose a first sidewall and a second sidewall, opposite to each other in a second direction, of each of the multiple transistor pillars.

### CROSS-REFERENCE TO RELATED APPLICATIONS

The application is filed based on Chinese Patent Application No. 202110750542.0 filed on Jul. 2, 2021, and claims priority to the Chinese Patent Application, the entire contents of which are incorporated herein by reference in its entirety.

### TECHNICAL FIELD

The disclosure relates to the technical field of semiconductor, and relates to, but is not limited to a transistor array and a method for manufacturing the same, and a semiconductor device and a method for manufacturing the same.

### BACKGROUND

A transistor is widely used as a switching device or a driving apparatus in an electronic device. For example, the transistor may be used in a Dynamic Random Access Memory (DRAM) to control a capacitor in each memory cell.

In the related art, a transistor mainly includes a planar transistor and a Buried Channel Array Transistor (BCAT). However, no matter whether the transistor is a planar transistor or a BCAT, its source S and drain D are located on two horizontal sides of its gate G respectively, and in this structure, the source and the drain occupy different positions respectively, which makes the area of the transistor larger. In addition, in a memory device, the source and the drain of the transistor are connected to different structures respectively after they are formed. When the source and the drain are located on two horizontal sides of the gate respectively, circuit wiring inside the memory is complicated and the manufacturing process thereof is difficult to be implemented.

### SUMMARY

In view of this, embodiments of the disclosure provide a transistor array and a method for manufacturing the same, and a semiconductor device and a method for manufacturing the same.

According to a first aspect, an embodiment of the disclosure provides a method for manufacturing a transistor array. The method may include the following operations.

A wafer is provided.

The wafer is partially etched from a first surface of the wafer along a first direction, to form a grid-like etched trench and a transistor pillar array, here the transistor pillar array includes multiple transistor pillars arranged in an array, each of the multiple transistor pillars has a first preset thickness smaller than an initial thickness of the wafer, the first direction is a thickness direction of the wafer and is perpendicular to the first surface.

An insulating material is deposited in the grid-like etched trench to form an insulating layer surrounding each of the multiple transistor pillars.

The insulating layer is etched to expose a first sidewall and a second sidewall, opposite to each other in a second direction perpendicular to the first direction, of each of the multiple transistor pillars.

A gate oxide layer and a gate are formed sequentially on each of the first sidewall and the second sidewall.

A source is formed at a first end of each of the multiple transistor pillars.

A drain is formed at a second end of each of the multiple transistor pillars, here the first end and the second end are opposite ends of each of the multiple transistor pillars in the first direction respectively, and a part of each of the multiple transistor pillars between the source and the drain forms a channel region of the transistor.

In some embodiments, the operation of etching the insulating layer to expose the first sidewall and the second sidewall, opposite to each other in the second direction, of each of the multiple transistor pillars may include the following operations.

The insulating layer is partially etched along the first direction with positions of a first edge and a second edge, opposite to each other in the second direction, of each of the multiple transistor pillars as the etching start point, to remove the insulating layer with a preset size in the second direction and with a second preset thickness in the first direction, to form multiple etched trenches arranged in parallel along the second direction.

Here each of the multiple etched trenches exposes a sidewall of each of the multiple transistor pillars arranged in parallel along a third direction correspondingly, a plane where the third direction and the second direction are located is perpendicular to the first direction, the third direction intersects with the second direction; the preset size is smaller than an interval between two adjacent transistor pillars in the second direction; and the second preset thickness is smaller than or equal to the first preset thickness.

In some embodiments, the operation of forming the gate oxide layer and the gate sequentially on each of the first sidewall and the second sidewall may include the following operations.

The gate oxide layer is formed by in-situ oxidation on each of the first sidewall and the second sidewall.

A conductive material is deposited in the etched trench formed with the gate oxide layer, to form a conductive layer.

The conductive layer is etched along the first direction, to remove part of the thickness of the conductive layer in the first direction to form the gate.

In some embodiments, the operation of forming the gate oxide layer and the gate sequentially on each of the first sidewall and the second sidewall may include the following operations.

An initial gate oxide layer is formed by in-situ oxidation on each of the first sidewall and the second sidewall.

A conductive material is deposited in the etched trench formed with the initial gate oxide layer, to form a conductive layer.

The initial gate oxide layer and the conductive layer are etched along the first direction, to remove part of the thicknesses of the initial gate oxide layer and the conductive layer in the first direction to form the gate.

In some embodiments, the method may further include the following operations after forming the gate oxide layer and the gate.

An isolation layer is formed by deposition in the etched trench, here a size of the isolation layer in the third direction is larger than a size of each of the multiple transistor pillars in the third direction.

In some embodiments, the method may further include the following operations before forming the drain.

The wafer is thinned from a second surface of the wafer until exposing the second end of each of the multiple transistor pillars, here the second surface of the wafer is a surface opposite to the first surface of the wafer.

In some embodiments, cross-sectional shapes of the source and the drain parallel to a preset plane are the same or different, and the preset plane is perpendicular to the first direction.

The cross-sectional shapes of the source and the drain parallel to the preset plane include any one of a square, a semicircle, a triangle, or any polygon.

In some embodiments, each of the multiple transistor pillars may be a columnar transistor pillar, and a length of each of the first sidewall and the second sidewall in the first direction is smaller than the first preset thickness.

In some embodiments, each of the multiple transistor pillars may be an inverted T-shaped transistor pillar, and a length of each of the first sidewall and the second sidewall in the first direction is equal to the first preset thickness.

According to a second aspect, an embodiment of the disclosure provides a transistor array, the transistor array including multiple transistors arranged in an array, each of the multiple transistors including a channel region, a source, a drain, double gates, a gate oxide layer and an isolation layer.

The source is located at a first end of the channel region.

The drain is located at a second end of the channel region, here the first end and the second end are opposite ends of the channel region in a first direction which is a thickness direction of a wafer forming the channel region.

The double gates are located on two sides of the channel region respectively, each of the double gates corresponds to the channel region.

The gate oxide layer is located between the channel region and each of the double gates.

The isolation layer is arranged on each of the double gates along the first direction and extends along a third direction, here a size of the isolation layer in the third direction is greater than a size of the channel region in the third direction, and the third direction is parallel to a column arrangement direction of the transistor array.

According to a third aspect, an embodiment of the disclosure provides a method for forming a semiconductor device. The method may include the following operations.

At least one memory array is formed, here each of the at least one memory array includes at least a columnar transistor array including multiple transistors arranged in an array, each of the multiple transistors includes double gates, a source and a drain, and the transistor array is manufactured by the method provided in the forgoing first aspect.

Multiple word lines arranged in parallel along a third direction are formed, here each of the multiple word lines is connected to the double gates of each of the multiple transistors arranged in parallel along the third direction, and is configured to provide a word line voltage and control each of the multiple transistors to be turned on or off by the word line voltage.

Multiple bit lines arranged in parallel along a second direction are formed, here each of the multiple bit lines is connected to the source or the drain of each of the multiple transistors arranged in parallel along the second direction, and is configured to perform a read or write operation on each of the at least one memory array when each of the multiple transistors is turned on, the third direction intersects with the second direction, and a plane where the third direction and the second direction are located is perpendicular to the first direction.

According to a fourth aspect, an embodiment of the disclosure provides a semiconductor device, the semiconductor device may include at least one memory array, multiple word lines arranged in parallel along a third direction, and multiple bit lines arranged in parallel along a second direction.

Here each of the at least one memory array includes at least the transistor array provided in the forgoing second aspect, each of the multiple transistors includes at least double gates, a source and a drain; and the third direction intersects with the second direction, and a plane where the third direction and the second direction are located is perpendicular to the first direction.

Each of the multiple word lines is connected to the double gates of each of the multiple transistors arranged in parallel along the third direction, and is configured to provide a word line voltage and control each of the multiple transistors to be turned on or off by the word line voltage.

Each of the multiple bit lines is connected to the source or the drain of each of the multiple transistors arranged in parallel along the second direction, and is configured to perform a read or write operation on each of the at least one memory array when each of the multiple transistors is turned on.

In some embodiments, each of the at least one memory array may further include a storage capacitor.

The storage capacitor has one end connected to the drain or the source of the transistor and the other end grounded, and is configured to store data written into each of the at least one memory array.

In some embodiments, each of the at least one memory array may further include a ferroelectric capacitor.

The ferroelectric capacitor includes an upper electrode, a lower electrode and a ferroelectric material layer located between the upper electrode and the lower electrode; the upper electrode of the ferroelectric capacitor is connected to the drain of the transistor, and the lower electrode of the ferroelectric capacitor is connected to the source of the transistor, and the ferroelectric capacitor is configured to store data written into each of the at least one memory array.

In some embodiments, each of the at least one memory array may further include an adjustable resistor.

The adjustable resistor is connected between the bit line and the source of the transistor, or is connected between the bit line and the drain of the transistor, and is configured to adjust a state of data stored in each of the at least one memory array by a bit line voltage provided by the bit line.

In some embodiments, when the semiconductor device includes multiple memory arrays, the multiple memory arrays may be connected in parallel or in series.

According to a transistor array and a method for manufacturing the same, and a semiconductor device and a method for manufacturing the same provided in the embodiments of the disclosure, since a source and a drain of a formed transistor are located at a first end and a second end of a channel region in a first direction respectively, and the first direction is a thickness direction of a wafer forming the channel region, the area of the transistor array is greatly reduced. In addition, the transistor provided in the embodiments of the disclosure may be used to form a memory, and since the drain and the source of the transistor are located on different surfaces of the wafer, different structures of the memory connected to the source and the drain may be designed on two surfaces of the wafer respectively, that is, designed on opposite surfaces of the wafer respectively, thereby simplifying the circuit layout inside the memory and reducing difficulty of the process of manufacturing the memory.

### BRIEF DESCRIPTION OF THE DRAWINGS

In the drawings (which are not necessary to be drawn to scale), similar reference numerals may describe similar components in different figures. Similar reference numerals with different suffix letters may indicate different examples of similar components. The drawings generally show various embodiments discussed herein by way of example without limitation.

FIG. TA illustrates a schematic structural diagram of a planar transistor in the related art.

FIG. 1B illustrates a schematic structural diagram of a BCAT in the related art.

FIG. 1C illustrates a schematic structural diagram of a DRAM memory array composed of planar transistors in the related art.

FIG. 1D illustrates a schematic structural diagram of a DRAM memory array composed of BCATs in the related art.

FIG. 2A illustrates a schematic structural diagram of a transistor array provided in an embodiment of the disclosure.

FIG. 2B illustrates a schematic structural diagram of another transistor array provided in an embodiment of the disclosure.

FIG. 3 illustrates a schematic flowchart of a method for manufacturing a transistor array provided in an embodiment of the disclosure.

FIGS. 4A to 4Q illustrate schematic process diagrams of a method for manufacturing a columnar transistor provided in an embodiment of the disclosure.

FIG. 5A illustrates a schematic structural diagram of a columnar transistor provided in an embodiment of the disclosure.

FIG. 5B illustrates a schematic structural diagram of another columnar transistor provided in an embodiment of the disclosure.

FIGS. 6A to 6I illustrate schematic process diagrams of a method for manufacturing an inverted T-shaped transistor provided in an embodiment of the disclosure.

FIG. 7A illustrates a schematic structural diagram of a semiconductor device provided in an embodiment of the disclosure.

FIG. 7B illustrates a schematic structural diagram of a part of a semiconductor device provided in an embodiment of the disclosure.

FIG. 7C illustrates a schematic structural diagram of a DRAM memory array provided in an embodiment of the disclosure.

FIG. 7D illustrates a schematic structural diagram of a Phase Change Memory (PCM) memory array provided in an embodiment of the disclosure.

FIG. 8 illustrates a schematic flowchart of a method for forming a semiconductor device provided in an embodiment of the disclosure.

### DETAILED DESCRIPTION

In order to make the objectives, technical solutions and advantages of embodiments of the disclosure clearer, the specific technical solutions of the disclosure are further described in detail below with reference to the drawings of the embodiments of the disclosure. The following embodiments are intended to illustrate the disclosure, but are not intended to limit the scope of the disclosure.

In the following descriptions, usage of suffixes such as “module” or “unit” used to indicate elements is only intended to facilitate the description of the disclosure, and has no specific meaning themselves. Therefore, “module” or “unit” may be used in a mixed manner.

In the related art, a transistor of a mainstream memory includes a planar transistors (Planar) and a BCAT. However, no matter whether the transistor is a planar transistor or a BCAT, its source and drain are located on two horizontal sides of its gate respectively according to its structure.

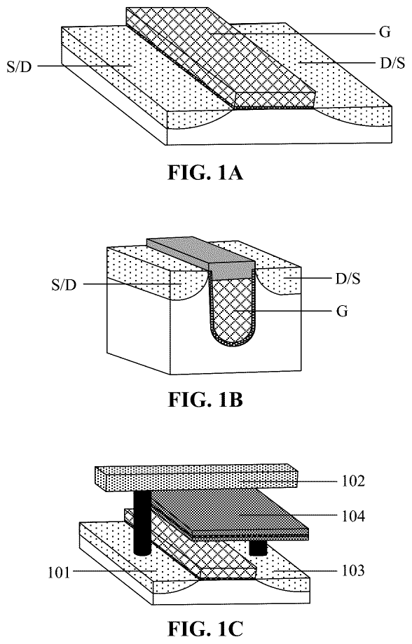

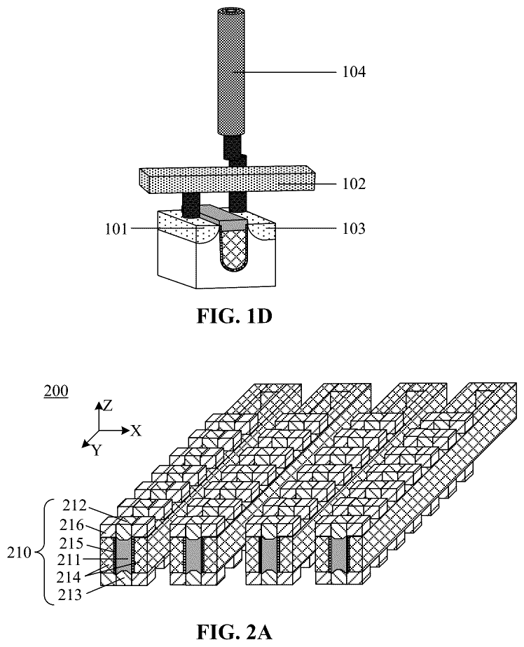

FIG. TA illustrates a schematic structural diagram of a planar transistor in the related art. FIG. 1B illustrates a schematic structural diagram of a BCAT in the related art. As illustrated in FIGS. 1A and 1B, the source S and the drain D of the transistor in the related art are located on two horizontal sides of the gate G respectively. In this way, the source and the drain occupy different positions on the horizontal plane respectively, so that no matter whether the transistor is a planar transistor or a BCAT, it has a larger horizontal area.

In addition, since the transistor may be prepared on a silicon substrate, the transistor may be used in various memories, such as DRAM. Generally, DRAM is composed of multiple memory arrays, each of which is mainly composed of a transistor and a capacitor controlled by the transistor. That is, DRAM is a memory array with one transistor and one capacitor C (1T1C).

FIG. 1C illustrates a schematic structural diagram of a DRAM memory array composed of planar transistors in the related art. FIG. 1D illustrates a schematic structural diagram of a DRAM memory array composed of BCATs in the related art. As illustrated in FIGS. 1C and 1D, the source (or the drain) 101 of the transistor in the DRAM memory array is connected to a bit line 102, and the drain (or the source) 103 thereof is connected to the capacitor 104. A chip composed of BCATs is usually packaged in a Chips on Board (COB) manner to form a memory.

Since the source and the drain of each of the planar transistor and the BCAT are located on two horizontal sides of the gate respectively, the bit line and capacitor in the DRAM memory array are also located on the same side of the gate, and the connection among the bit line, the transistor and the capacitor, the connection between the word line (WL) and the transistor, etc., need to be made in subsequent processes, which leads to complicated circuit wiring in a memory array region of the DRAM memory and a more difficult manufacturing process.

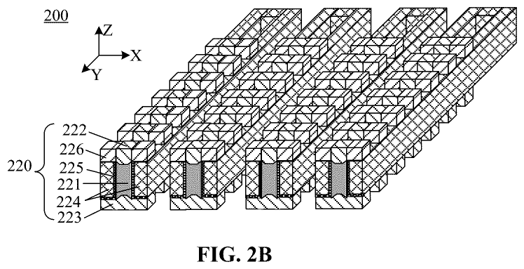

FIG. 2A illustrates a schematic structural diagram of a transistor array 200 provided in an embodiment of the disclosure. Referring to FIG. 2A, the transistor array 200 includes multiple transistors arranged in an array, each of the multiple transistors including a columnar transistor 210.

FIG. 2B illustrates a schematic structural diagram of another transistor array 200 provided in an embodiment of the disclosure. Referring to FIG. 2B, the transistor array 200 includes multiple transistors arranged in an array, each of the multiple transistors including an inverted T-shaped transistor 220.

For example, the multiple transistors arranged in an array may be arranged as follows: N transistors are arranged in parallel along an X-axis direction and M transistors are arranged in parallel along a Y-axis direction. In this way, a transistor array 200 composed of N*M transistors may be formed. It may be understood that both N and M are natural numbers, and values of N and M cannot take 1 at the same time.

Specifically, FIG. 2A illustrates a schematic structural diagram of a columnar transistor 210 provided in an embodiment of the disclosure. Referring to FIG. 2A, the columnar transistor 210 includes a channel region 211, a source 212, a drain 213, double gates 214, a gate oxide layer 215 and an isolation layer 216.

The source 212 is located at a first end of the channel region 211.

The drain 213 is located at a second end of the channel region 211, here the first end and the second end are opposite ends of the channel region 211 in a first direction which is a thickness direction of a wafer forming the channel region 211.

The double gates 214 are located on two sides of the channel region 211 respectively, each of the double gates corresponds to the channel region 211.

The gate oxide layer 215 is located between the channel region 211 and each of the double gates.

The isolation layer 216 is arranged on each of the double gates along the first direction and extends along a third direction, here a size of the isolation layer in the third direction is greater than a size of the channel region 211 in the third direction, and the third direction is parallel to a column arrangement direction of the transistor array 200.

It may be understood that the columnar transistor 210 provided in the embodiment of the disclosure has a vertical channel (that is, the channel region 211), and the source 212 and the drain 213 of the columnar transistor 210 are located at opposite ends (that is, the first end and the second end) of the vertical channel respectively. Positions of the source 212 and the drain 213 may be interchanged.

For example, the first direction may be parallel to a Z-axis direction, a row arrangement direction of the transistor array 200 may be parallel to an X-axis direction, and a column arrangement direction of the transistor array 200 may be parallel to a Y-axis direction.

The gate oxide layer 215 is configured to electrically isolate the channel region 211 from each of the double gates 214.

The third direction is parallel to the column arrangement direction of the transistor array 200, and the column arrangement direction of the transistor array may be parallel to the Y-axis. Gate oxide layers of multiple transistors located at the same column form an integral structure, and gates of multiple transistors located at the same column form an integral structure. In this way, in the third direction, a size of the gate oxide layer is greater than a size of the channel region 211, and a size of each of the double gates is greater than a size of the channel region 211.

In the embodiment of the disclosure, the source 212 and the drain 213 are located at opposite ends of the wafer forming the channel region 211 in the thickness direction respectively, that is, the source 212 and the drain 213 of the columnar transistor 210 provided in the embodiment of the disclosure are located at opposite surfaces of the wafer. In this way, the area of the transistor is greatly reduced.

FIG. 3 illustrates a schematic flowchart of a method for manufacturing a transistor array provided in an embodiment of the disclosure. As shown in FIG. 3, the method for manufacturing a transistor array provided in the embodiment of the disclosure may include the following operations.

In operation S301, a wafer is provided.

In operation S302, the wafer is partially etched from a first surface of the wafer along a first direction, to form a grid-like etched trench and a transistor pillar array, here the transistor pillar array includes multiple transistor pillars arranged in an array, each of the multiple transistor pillars has a first preset thickness smaller than an initial thickness of the wafer; and the first direction is a thickness direction of the wafer and is perpendicular to the first surface.

In operation S303, an insulating material is deposited in the grid-like etched trench to form an insulating layer surrounding each of the multiple transistor pillars.

In operation S304, the insulating layer is etched to expose a first sidewall and a second sidewall, opposite to each other in a second direction perpendicular to the first direction, of each of the multiple transistor pillars.

In operation S305, a gate oxide layer and a gate are formed sequentially on each of the first sidewall and the second sidewall.

In operation S306, a source is formed at a first end of each of the multiple transistor pillars.

In operation S307, a drain is formed at a second end of each of the multiple transistor pillars.

Here the first end and the second end are opposite ends of each of the multiple transistor pillars in the first direction respectively, and a part of each of the multiple transistor pillars between the source and the drain forms a channel region of the transistor.

In the embodiment of the disclosure, the provided wafer may include at least one transistor array formation region. The transistor array formation region is a region forming a transistor array on the wafer. The transistor array formation region may form multiple transistor pillars arranged in an array, and each of the multiple transistor pillars has exposed first and second sidewalls which are opposite to each other in the first direction. The transistor array formation region may further form an insulating layer surrounding other sidewalls of the respective transistor pillar.

It may be understood that the exposed first and second sidewalls of the transistor pillar are not surrounded by the insulating layer. The transistor pillar includes an upper surface, a lower surface and a sidewall. The upper surface and the lower surface of the transistor pillar are perpendicular to the first direction. The sidewall of the transistor pillar is located between a plane where the upper surface of the transistor pillar is located and a plane where the lower surface of the transistor pillar is located.

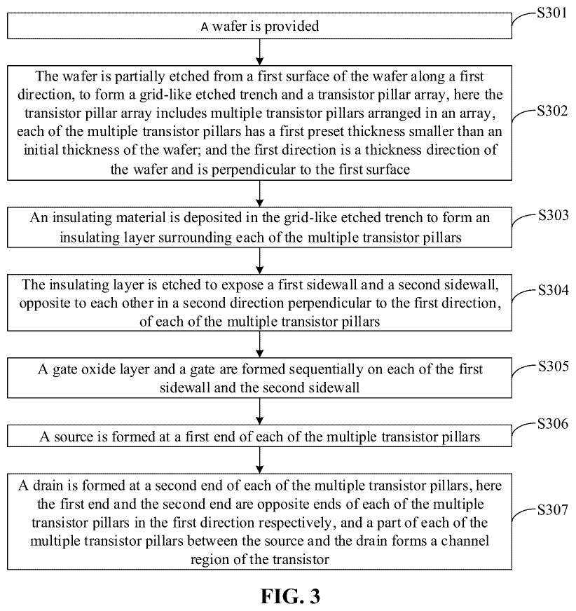

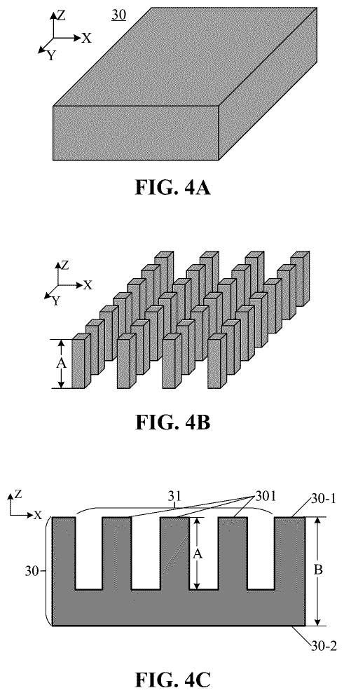

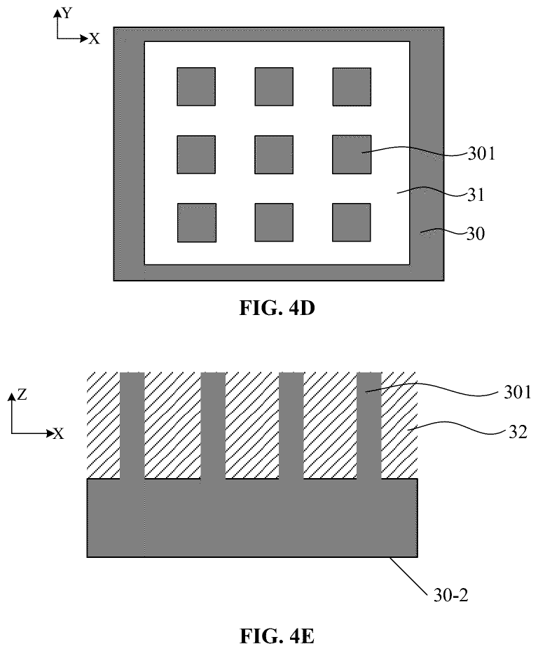

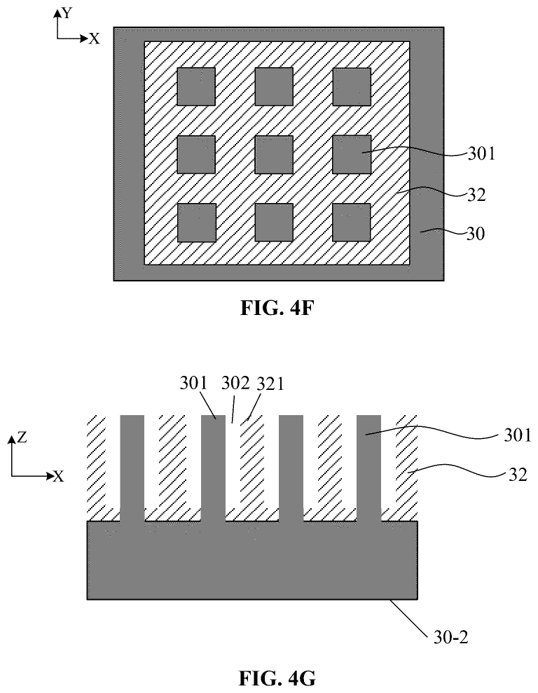

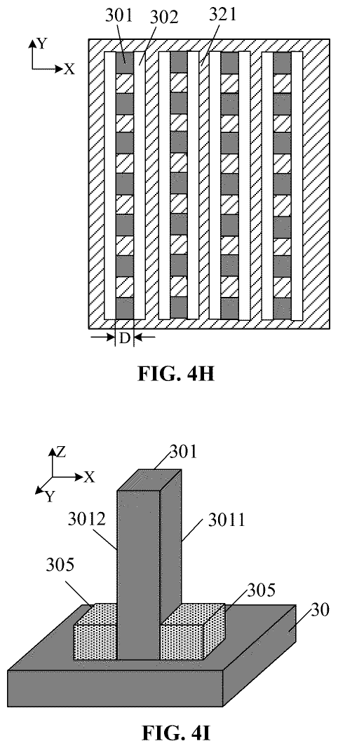

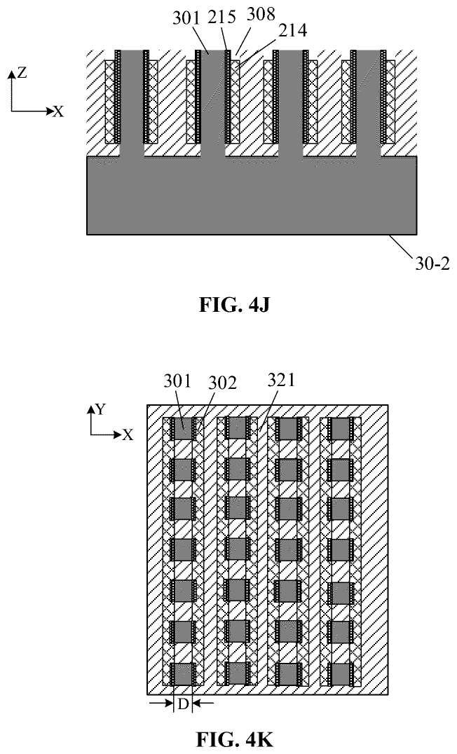

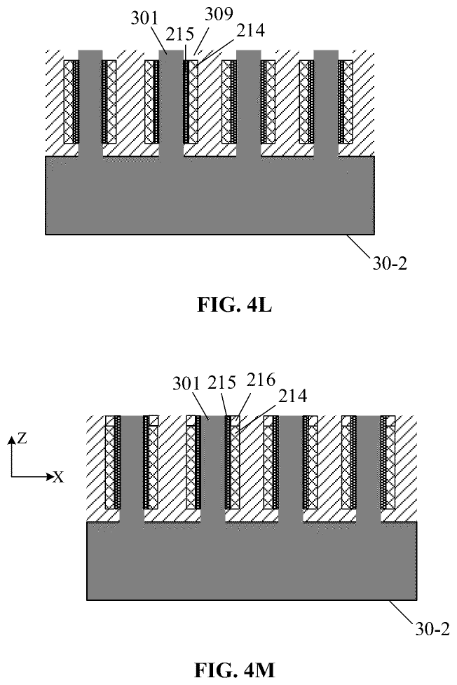

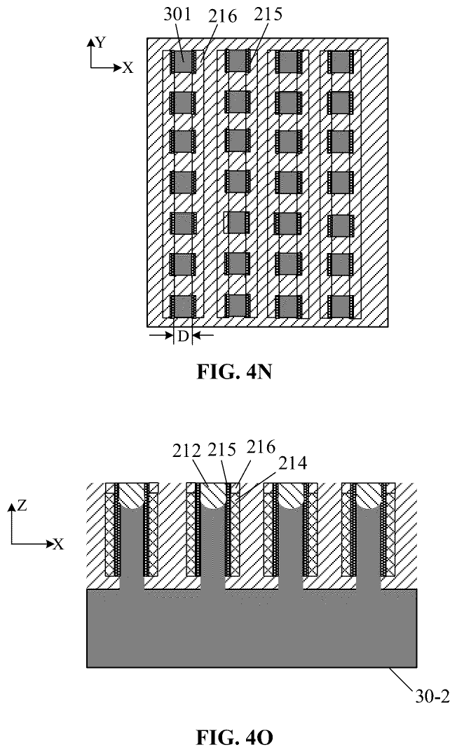

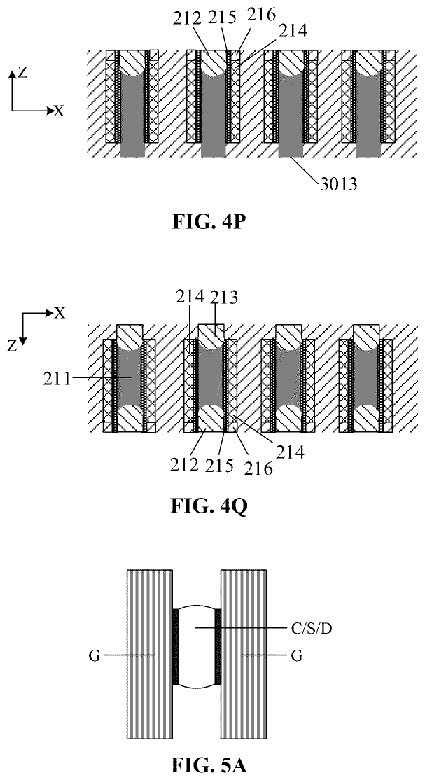

In some embodiments, the transistor may include the columnar transistor 210. Next, referring to FIGS. 4A to 4H, the method for manufacturing the columnar transistor 210 provided in the embodiment of the disclosure is further described in detail.

First, referring to FIG. 4A, the operation S301 is performed, in which a wafer 30 is provided. The wafer may include at least one transistor array formation region as described above. The wafer may be made of silicon, germanium, and other semiconductor materials.

In the operation S302, the first surface of the wafer is any surface of the wafer in the first direction.

The thickness direction of the wafer is defined as the first direction. A second direction and a third direction intersecting with each other are defined in a top surface or a bottom surface of the wafer perpendicular to the first direction, and the top surface or the bottom surface of the wafer perpendicular to the first direction may be determined based on the second direction and the third direction.

In some embodiments, the second direction is perpendicular to the third direction. In this way, any two of the first direction, the second direction and the third direction are perpendicular to each other. The first direction may be defined as the Z-axis direction, the second direction may be defined as the X-axis direction, and the third direction may be defined as the Y-axis direction.

In some embodiments, the second direction intersects with the third direction, but is not perpendicular to the third direction, that is, the angle between the second direction and the third direction may be any angle.

FIG. 4B illustrates a three-dimensional (3D) diagram of a transistor pillar array provided in an embodiment of the disclosure. FIG. 4C illustrates a cross-sectional view of a grid-like etched trench in a first direction provided in an embodiment of the disclosure. FIG. 4D illustrates a top view of a grid-like etched trench provided in an embodiment of the disclosure.

It may be seen with reference to FIGS. 4B to 4D that the wafer 30 is partially etched along the Z-axis direction with a first surface 30-1 of the wafer as an etching start point, to form a grid-like etched trench 31 and a transistor pillar array including multiple transistor pillars 301. Each of the multiple transistor pillars 301 is located at a grid point of the grid. Gaps between any two adjacent transistor pillars may be equal.

Referring to FIG. 4C, each of the multiple transistor pillars 301 has a first preset thickness A in the Z-axis direction which is smaller than an initial thickness B of the wafer. The first surface 30-1 of the wafer is any surface of the wafer perpendicular to the Z-axis direction. The wafer further includes a second surface 30-2 opposite to the first surface 30-1.

Here the wafer may be etched by a dry etching process, for example, a plasma etching process or a reactive ion etching process. It is worth noting that in the embodiments of the disclosure, the etching of the wafer is a partial etching performed along the thickness direction of the wafer, that is, the wafer will not be cut through during etching.

It should be noted that FIG. 4B only illustrates a partial region of the transistor pillar array, and a part of the wafer that is not cut through below the transistor pillar is omitted.

FIG. 4E illustrates a cross-sectional view in a first direction after an insulating layer is formed in a grid-like etched trench provided in an embodiment of the disclosure. FIG. 4F illustrates a top view after an insulating layer is formed in a grid-like etched trench provided in an embodiment of the disclosure. As shown in FIGS. 4E and 4F, an insulating material is deposited in the grid-like etched trench 31, and an insulating material is filled around each of the multiple transistor pillars 301 to form an insulating layer 32. The insulating material may be silicon dioxide (SiO2) material or another electrical insulating material.

It should be noted that during actual deposition of the insulating material, the insulating material will cover the upper surface of the transistor pillar 301. Generally, after the deposition is completed, a Chemical Mechanical Polishing (CMP) process is used to remove excess insulating material to expose the upper surface of the transistor pillar 301. It may be understood that the upper surface of the transistor pillar is a surface of the transistor pillar relatively close to the first surface 30-1 in the Z-axis direction.

FIG. 4G illustrates a cross-sectional view of a structure obtained after the operation S304 is performed, in a first direction provided in an embodiment of the disclosure. FIG. 4H illustrates a top view of a structure obtained after the operation S304 is performed, provided in an embodiment of the disclosure. As shown in FIGS. 4G and 4H, the operation S304 may include the following operations.

The insulating layer 32 is partially etched along the first direction with positions of a first edge and a second edge, opposite to each other in the second direction, of each of the multiple transistor pillars as an etching start point, to remove the insulating layer with a preset size in a second direction and with a second preset thickness in the first direction, to form multiple etched trenches 302 arranged in parallel along the second direction, here each of the multiple etched trenches 302 exposes the sidewall of each of the multiple transistor pillars 301 arranged in parallel along a third direction correspondingly.

Here two sides, opposite to each other in the second direction, of each of the multiple transistor pillars 301, have the etched trenches 302 respectively, and the etched trenches 302 on two sides of each of the multiple transistor pillars 301 expose the first sidewall and the first sidewall of each of the multiple transistor pillars respectively. The etching with the position of the first edge as the etching start point exposes the first sidewall of the transistor pillar, and the etching with the position of the second edge as the etching start point exposes the second sidewall of the transistor pillar. A length of each of the first sidewall and the second sidewall in the first direction is smaller than the first preset thickness.

It may be understood that positions of the first edge and the second edge of each of the multiple transistor pillars are in contact with the insulating layer, and the remaining insulating material after the etched trench 302 is formed forms an insulating layer 321.

In some embodiments, the method may further include the following operations when the operation S304 is performed.

Each of the multiple transistor pillars is partially etched along the first direction with positions of a first edge and a second edge, opposite to each other in the second direction, of each of the multiple transistor pillars as the etching start point, to remove the transistor pillar with a preset size in the second direction and with a second preset thickness in the first direction.

It may be understood that after the insulating layer and the transistor pillar having the second preset thickness in the first direction are removed, the foregoing multiple etched trenches arranged in parallel along the second direction may be formed.

It should be noted that multiple transistor arrays 200 may be formed on a wafer. In the embodiments of the disclosure, only a transistor array 200 composed of a limited number of transistors or a partial region of the transistor array is shown as an example, for ease of description.

In some embodiments, the method for manufacturing the transistor array 200 may further include the following operations before the operation S305 is performed.

An insulated bottom isolation layer is formed by deposition at the bottom of the etched trench.

Here material of the bottom isolation layer includes but is not limited to any one of silicon nitride, silicon oxynitride, silicon carbide, or silicon dioxide. The bottom isolation layer is configured to electrically isolate the gate of the transistor from the wafer material whose bottom is not cut through.

Next, a transistor pillar on a wafer is used as an example to describe a structure after the bottom isolation layer is formed.

Specifically, as shown in FIG. 4I, a first sidewall 3011 and a second sidewall 3012 of the transistor pillar 301 are exposed by the etched trench, a bottom isolation layer 305 is formed by deposition at the bottom of the etched trench (not shown in FIG. 4I), and is in contact with the first sidewall 3011 and the second sidewall 3012. Here the bottom isolation layer 305 may be formed by deposition with any suitable deposition process.

In some embodiments, when the etched trench is formed by removing the insulating layer having the second preset thickness and the second preset thickness is smaller than the first preset thickness of the transistor pillar, there is an insulating layer remained at the bottom of the etched trench, and a thickness of the remaining insulating layer is a difference between the first preset thickness and the second preset thickness. The remaining insulating layer may act as the bottom isolation layer. In this way, an extra bottom isolation layer is not required to be formed. In other words, the insulating layer remained at the bottom of the etched trench may be taken as the bottom isolation layer.

In some embodiments, the operation S305 may include the following operations.

The gate oxide layer 215 is formed by in-situ oxidation on the exposed sidewall of each of the multiple transistor pillars.

A conductive material is deposited in the etched trench formed with the gate oxide layer 215, to form a conductive layer 214.

The conductive layer is etched along the first direction, to remove part of the thickness of the conductive layer in the first direction to form the gate.

FIG. 4J illustrates a cross-sectional view in a first direction of a formed gate oxide layer and gate provided in an embodiment of the disclosure. FIG. 4K illustrates a top view of a formed gate oxide layer and gate provided in an embodiment of the disclosure.

For example, the situ-oxidation may be performed on the exposed first sidewall 3011 and second sidewall 3012 of the transistor pillar 301 by heating or pressurization, to form the gate oxide layer 215. As shown in FIG. 4K, in the Y-axis direction, a size of the gate oxide layer 215 formed by oxidizing the first and second sidewalls of the transistor pillar is substantially the same as a size of the transistor pillar 301.

In some embodiments, the gate oxide layer may further be formed by deposition. The gate oxide layer covers the first and second sidewalls exposed by the etched trench. It should be noted that the gate oxide layer formed by deposition not only covers the first and second sidewalls exposed by the etched trench, but also covers a sidewall of an insulating layer between adjacent transistor pillars exposed by the etched trench. In this way, in the Y-axis direction, a size of the gate oxide layer formed by deposition may be greater than the size of the transistor pillar.

Here the conductive material may be deposited in the etched trench by a Chemical Vapor Deposition (CVD), Physical Vapor Deposition (PVD) or Atomic Layer Deposition (ALD) process to form the conductive layer.

For example, the conductive material may include polysilicon, conductive metal, conductive alloy or the like. The conductive metal may include metal such as tungsten, copper or the like.

As shown in FIG. 4J, the foregoing formed conductive material is partially etched along the Z-axis direction, to form a trench 308, and the remaining conductive material is used as the gate 214.

In some embodiments, the operation S305 may include the following operations.

An initial gate oxide layer is formed by in-situ oxidation on each of the exposed first and second sidewalls of each of the multiple transistor pillars.

A conductive material is deposited in the etched trench formed with the initial gate oxide layer, to form a conductive layer.

The initial gate oxide layer and the conductive layer are etched along the first direction, to remove part of the thicknesses of the initial gate oxide layer and the conductive layer in the first direction to form the gate oxide layer and the gate.

As shown in FIG. 4L, in the Z-axis direction, the foregoing formed initial gate oxide layer and the conductive material are partially etched to form a trench 309, the remaining initial gate oxide layer is used as the gate oxide layer 215, and the remaining conductive material is used as the gate 214.

In the embodiments of the disclosure, the foregoing etching process may be implemented by using a dry etching technology.

In some embodiments, the method for manufacturing the transistor array 200 may further include the following operations after forming the gate oxide layer and the gate.

An isolation layer 216 is formed by deposition in the etched trench, here a size of the isolation layer 216 in the third direction is greater than a size of each of the multiple transistor pillars in the third direction.

Here material of the isolation layer includes but is not limited to any one of silicon nitride, silicon oxynitride, silicon carbide, or silicon dioxide. The isolation layer and the bottom isolation layer have the same or different materials.

FIG. 4M illustrates a cross-sectional view of a structure obtained after an isolation layer 216 is formed, in a first direction provided in an embodiment of the disclosure.

FIG. 4N illustrates a top view after an isolation layer is formed, provided in an embodiment of the disclosure.

As shown in FIG. 4N, the transistor pillar 301 is located within a projection region of the isolation layer 216 in the X-axis direction. In addition, in the Y-axis direction, a size of the transistor pillar 301 is smaller than a size of the isolation layer 216.

Next, referring to FIG. 4O, the operation S306 is performed. Here the first end of the transistor pillar is an end of the transistor pillar in the Z-axis direction. As shown in FIG. 4O, the source 212 is formed by performing ion implantation on the first end of the transistor pillar.

In some embodiments, a cross-section shape of the source 212 parallel to a preset plane includes any one of a square, a semicircle, a triangle, or any polygon. Here the preset plane is perpendicular to the first direction.

In some embodiments, the method for manufacturing the transistor array may further include the following operations before the operation S306 is performed.

The wafer is thinned from a second surface of the wafer until exposing the second end of each of the multiple transistor pillars.

As shown in FIG. 4O, the second surface 30-2 of the wafer is a surface opposite to the first surface 30-1 of the wafer.

In some embodiments, before the operation of thinning the second surface of the wafer is performed, the first surface of the wafer needs to be fixed onto a support structure to prevent the structure of the transistor from being damaged when the second surface 30-2 of the wafer is thinned.

FIG. 4P illustrates a schematic structural diagram of a transistor after a second surface of a wafer is thinned provided in an embodiment of the disclosure. As shown in FIG. 4P, the second surface of the wafer is thinned to expose a second end 3013 of the transistor pillar.

Next, referring to FIG. 4Q, the operation S307 is performed. Specifically, as shown in FIG. 4Q, the drain 213 is formed by performing ion implantation on the second end 3013 of the transistor pillar.

In some embodiments, cross-section shapes of the source 212 and the drain parallel to the forgoing preset plane may be the same or different. For example, the cross-section shape of the drain parallel to the preset plane includes any one of a square, a semicircle, a triangle, or any polygon.

In some embodiments, a channel of the columnar transistor 210 provided in an embodiment of the disclosure is parallel to the Z-axis direction, and cross-section shapes of the source, the drain and the channel C includes any one of a rectangle (a square), a semicircle, a triangle, or any polygon.

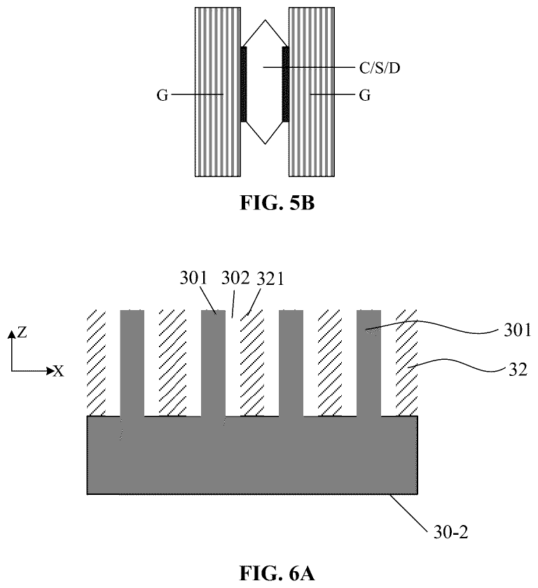

FIGS. 5A and 5B illustrate optional schematic structural diagrams of a columnar transistor 210 provided in an embodiment of the disclosure. As shown in FIG. 5A, cross-section shapes of the source, the drain and the channel of the double-gate transistor may be semicircles. As shown in FIG. 5B, cross-section shapes of the source, the drain and the channel of the double-gate transistor may be triangles.

It should be noted that positions of the source 212 and the drain may be interchanged, and the source 212 may be formed first or the drain may be formed first.

Please continue referring to FIG. 4Q, in the embodiment of the disclosure, after the source 212 and the drain are formed, a part of each of the multiple transistor pillars between the source 212 and the drain forms a channel region 211 of the columnar transistor 210.

In the columnar transistor 210 formed by using the manufacturing method provided in the embodiment of the disclosure, the source 212 and the drain are located at the first end and the second end of the channel region 211 in the first direction respectively, and the first direction is a thickness direction of a wafer forming the channel region 211. In this way, the area of the transistor array is greatly reduced.

In some embodiments, when the columnar transistor 210 provided in the embodiments of the disclosure is applied to a memory, since the drain and the source 212 of the columnar transistor 210 are located on different surfaces of the wafer, different structures of the memory connected to the source 212 and the drain may be designed on two surfaces of the wafer respectively, thereby simplifying the circuit layout inside the memory and reducing difficulty of the process of manufacturing the memory.

FIG. 2B illustrates a schematic structural diagram of an inverted T-shaped transistor 220 provided in an embodiment of the disclosure. Referring to FIG. 2B, the inverted T-shaped transistor 220 includes a channel region 221, a source 222, a drain 223, double gates 224, a gate oxide layer 225 and an isolation layer 226.

The source 222 is located at a first end of the channel region 221.

The drain 223 is located at a second end of the channel region 221, here the first end and the second end are opposite ends of the channel region 221 in a first direction which is a thickness direction of a wafer forming the channel region 221.

The double gates 224 are located on two sides of the channel region 221 respectively, each of the double gates corresponds to the channel region 211.

The gate oxide layer 225 is located between the channel region 221 and each of the double gates 224.

The isolation layer 226 is arranged on each of the double gates 224 along the first direction and extends along a third direction, here a size of the isolation layer 226 in the third direction is greater than a size of the channel region 221 in the third direction, and the third direction is parallel to a row arrangement direction or a column arrangement direction of the transistor array 200.

It may be understood that that an active region of the inverted T-shaped transistor 220 forms an inverted T-shaped structure, that is, the source, the drain and the channel region of the inverted T-shaped transistor 220 form an inverted T-shaped structure together.

It should be noted that a length of each of the first sidewall and the second sidewall of the inverted T-shaped transistor 220 in the first direction is equal to the first preset thickness.

It may be seen from FIG. 2B that each of two sides, opposite to each other in the second direction, of a transistor pillar of the inverted T-shaped transistor has an L-shaped surface. In a plane XOZ, double sources 222, the channel region 221 and the drain of the inverted T-shaped transistor form an inverted T-shaped structure.

In the embodiment of the disclosure, the source 222 and the drain are located at opposite ends of the wafer forming the channel region 221 in the thickness direction respectively, that is, the source 222 and the drain of the inverted T-shaped transistor provided in the embodiment of the disclosure are located at opposite surfaces of the wafer. In this way, the area of the transistor is greatly reduced.

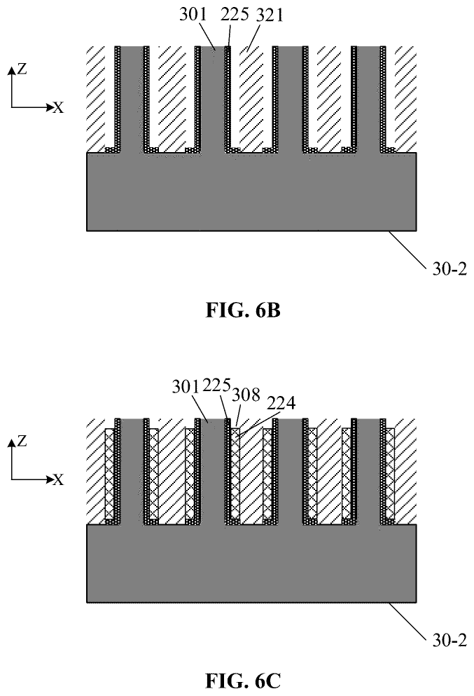

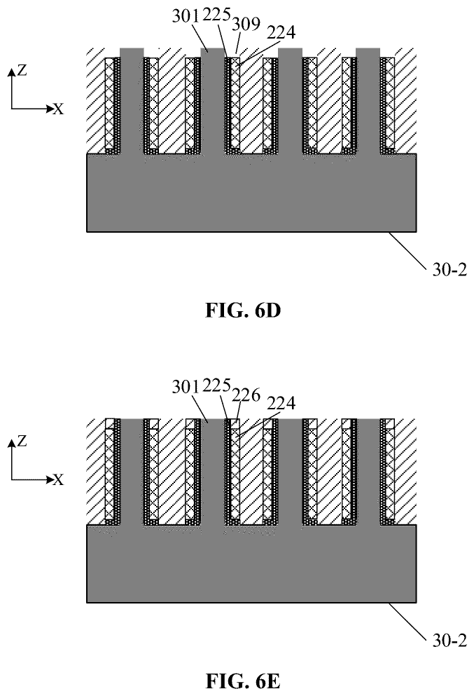

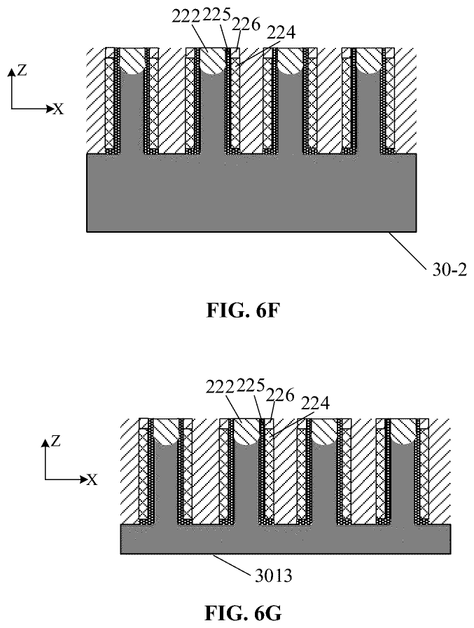

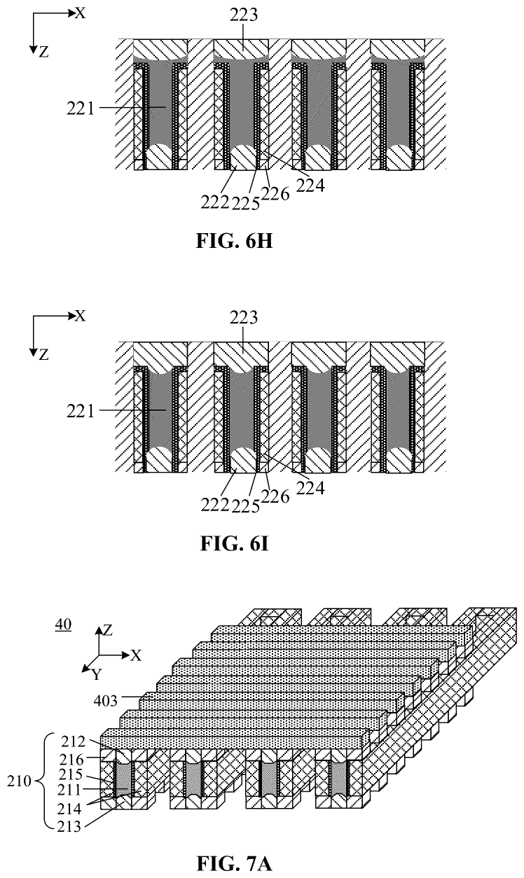

Next, referring to FIGS. 6A to 6H, a method for manufacturing an inverted T-shaped transistor provided in the embodiment of the disclosure is further described in detail.

First, the operation S301 is performed, in which a wafer is provided. The wafer may include at least one transistor array formation region as described above. Each of the at least one transistor array formation region may be configured to form a transistor array including multiple transistors. Each of the multiple transistors includes a transistor pillar, and each of two sides, opposite to each other in the second direction, of each of the transistor pillars has an exposed L-shaped surface.

It should be noted that in the method for manufacturing the columnar transistor 210 and the method for manufacturing the inverted T-shaped transistor, formation and processes of the operations S302 and S303 may be the same, and shapes and appearances of the formed grid-like etched trenches may be the same.

FIG. 6A illustrates a cross-sectional view of a structure obtained after the operation S304 is performed, in a first direction provided in an embodiment of the disclosure. As shown in FIG. 6A, the operation S304 may include the following operations.

The insulating layer 32 is partially etched along the first direction with positions of a first edge and a second edge, opposite to each other in the second direction, of each of the multiple transistor pillars as the etching start point, to remove the insulating layer with a preset size in a second direction and with a third preset thickness in the first direction, to form multiple etched trenches 303 arranged in parallel along the second direction, here the third preset thickness is greater than the second preset thickness, and the third preset thickness is equal to the first preset thickness of the transistor pillar.

Here two sides, opposite to each other in the second direction, of each of the multiple transistor pillars 301, have the etched trenches 302 respectively, and the etched trenches 302 on two sides of each of the multiple transistor pillars 301 expose the first sidewall and the first sidewall of each of the multiple transistor pillars respectively. The etching with the position of the first edge as the etching start point exposes the first sidewall of the transistor pillar, and the etching with the position of the second edge as the etching start point exposes the second sidewall of the transistor pillar. A length of each of the first sidewall and the second sidewall in the first direction is equal to the first preset thickness.

It should be noted that the insulating layer having a third preset thickness in the first direction is removed by etching, and the third preset thickness is equal to the first preset thickness of the transistor pillar, thus a part of the wafer is also exposed at the bottom of the etched trench 302. Here the first sidewall and bottom wafer exposed by the etched trench 302 are collectively referred to as an L-shaped surface, and the second sidewall and bottom wafer exposed by the etched trench 302 are collectively referred to as an L-shaped surface.

It should be noted that the bottom of the etched trench overlaps with the bottom of the grid-like etched trench. In an embodiment, in the first direction, the bottom of the etched trench is relatively close to the second surface 30-2 of the wafer, and the bottom of the grid-like etched trench is relatively far away from the second surface 30-2 of the wafer.

Next, referring to FIGS. 6B and 6C, the operation S305 is performed, in which a gate oxide layer and a gate are formed sequentially on the sidewall of each of the multiple transistor pillars. Specifically, the operation S305 may include the following operations.

The gate oxide layer 225 is formed by in-situ oxidation on each L-shaped surface exposed at two sides of each of the multiple transistor pillars in the first direction.

A conductive material is deposited in the etched trench 303 formed with the gate oxide layer 225, to form a conductive layer.

The conductive layer is etched along the first direction, to remove part of the thickness of the conductive layer in the first direction, to form the trench 308, and the remaining conductive layer forms the gate 224.

In some embodiments, the gate oxide layer may further be formed by deposition. The gate oxide layer covers the first and second sidewalls exposed by the etched trench and the bottom of the etched trench.

In some embodiments, the operation S305 may include the following operations.

An initial gate oxide layer is formed by in-situ oxidation on each L-shaped surface exposed at two sides of each of the multiple transistor pillars in the first direction.

A conductive material is deposited in the etched trench formed with the initial gate oxide layer, to form a conductive layer.

The initial gate oxide layer and the conductive layer are etched along the first direction, to remove part of the thicknesses of the initial gate oxide layer and the conductive layer in the first direction to form the gate oxide layer 225 and the gate 224 respectively.

As shown in FIG. 6D, in the Z-axis direction, the foregoing formed initial gate oxide layer and the conductive material are partially etched to form a trench 309, the remaining initial gate oxide layer is used as the gate oxide layer 225, and the remaining conductive material is used as the gate 224.

In some embodiments, as shown in FIG. 6E, the method for manufacturing the inverted T-shaped transistor may further include the following operations after forming the gate oxide layer and the gate.

The isolation layer 226 is formed by deposition in the etched trench 303, here a size of the isolation layer 226 in the third direction is greater than a size of the transistor pillar in the third direction.

It may be understood that after forming the gate oxide layer and the gate, a remaining space of the etched trench 303 is used as the trench 308 (as shown in FIG. 6C) or the trench 309 (as shown in FIG. 6D), therefore, the second isolation layer 226 fills the trench 308 (as shown in FIG. 6E) or the trench 309.

Next, referring to FIG. 6F, the operation S306 is performed. Specifically, the source 222 may be formed by performing ion implantation on the first end of the transistor pillar in the first direction.

In some embodiments, referring to FIGS. 6F and 6G, the method for manufacturing the transistor may further include the following operations before the operation S307 is performed.

The wafer is thinned from a second surface 30-2 of the wafer, to remove the wafer with a fourth preset thickness and expose the second end of the transistor pillar.

Here please continue referring to FIG. 6F, the second surface 30-2 of the wafer is a surface opposite to the first surface 30-1 of the wafer. The fourth preset thickness is smaller than a difference between an initial thickness of the wafer and the second preset thickness.

An example in which the wafer is made of silicon is used, and in the embodiment of the disclosure, when silicon of the second surface of the wafer is thinned, it needs to ensure that a thickness of silicon remains at the bottom of the etched trench 303.

In other embodiments, before the operation of thinning the second surface of the wafer is performed, the first surface of the wafer needs to be fixed onto a support structure to prevent the structure (for example, the structure of the transistor) formed at the first surface of the wafer from being damaged when the second surface 30-2 of the wafer is thinned.

As shown in FIG. 6G, the second surface of the wafer is thinned to remove the wafer with the fourth preset thickness, to expose the second end 3013 of the transistor pillar from the second surface of the wafer.

In some embodiments, the method may further include the following operations after thinning the second surface of the wafer to remove the wafer with the fourth preset thickness.

The exposed second end of the transistor pillar is etched from the second surface of the wafer to form a grid-like etched trench, to expose an insulating layer.

An insulating material is filled into the grid-like etched trench to form an electrical insulating layer, here the grid-like electrical insulating layer is configured to electrically isolate adjacent inverted T-shaped transistor pillars.

Next, referring to FIG. 6H, the operation S307 is performed and may include the following operations.

Ion implantation is performed on the second end 3013 of the transistor pillar to a preset depth to form the drain, here the preset depth is smaller than or equal to the difference between the initial thickness and the second preset thickness.

Here the depth of performing ion implantation on the drain may be a preset depth set in advance, and a maximum value of the preset depth may be equal to the difference between the initial thickness of the wafer and the second preset thickness.

FIG. 6H illustrates an optional schematic structural diagram of a formed drain provided in an embodiment of the disclosure. Here a first preset depth is smaller than a difference between the first preset thickness and the second preset thickness. In addition, a T-shaped channel region 221 is formed between the source 222 and the drain 223.

FIG. 6I illustrates an optional schematic structural diagram of a formed drain provided in an embodiment of the disclosure. As shown in FIG. 6I, the drain 223 is formed by performing ion implantation on the second end 3012 of the transistor pillar to a second preset depth. The second preset depth is basically equal to the difference between the first preset thickness and the second preset thickness. In addition, a vertical channel region 221 is formed between the source 222 and the drain 223.

In the embodiments of the disclosure, the finally formed transistor is an inverted T-shaped transistor from an overall view point, that is, the source 222, the drain and the channel region 221 of the inverted T-shaped transistor form an inverted T-shaped structure together. Here the channel region 221 of the inverted T-shaped transistor may be a T-shaped channel region (as shown in FIG. 6H), or may be a vertical channel region (as shown in FIG. 6I).

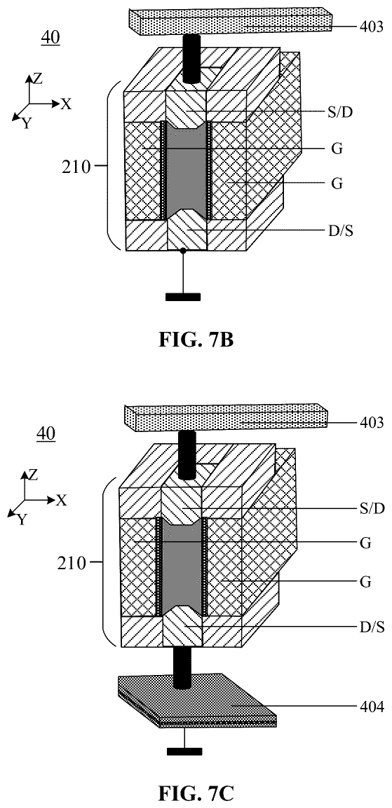

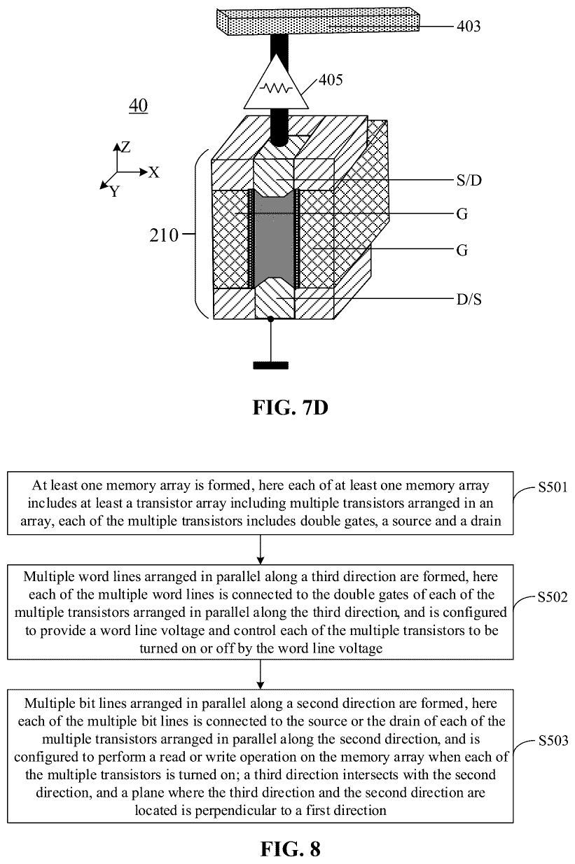

Embodiments of the disclosure provide a semiconductor device. FIG. 7A illustrates an optional schematic structural diagram of a semiconductor device provided in an embodiment of the disclosure. FIG. 7B illustrates a schematic structural diagram of a part of a semiconductor device provided in an embodiment of the disclosure. With reference to FIGS. 7A and 7B, a semiconductor device 40 includes at least one memory array, multiple word lines arranged in parallel along a third direction, and multiple bit lines 403 arranged in parallel along a second direction.

In some embodiments, double gates are used as the word line.

Each of at least one memory array includes multiple memory cells arranged in an array, each of the multiple memory cells includes at least one transistor provided in the embodiment of the disclosure. It should be noted that each of the at least one memory array includes the transistor array 200 provided in the embodiment of the disclosure.

In some embodiments, the transistor in the semiconductor device includes a columnar transistor 210. In some embodiments, the transistor in the semiconductor device may include an inverted T-shaped transistor 220.

It may be understood that no matter whether the transistor in the semiconductor device is the columnar transistor 210 or the inverted T-shaped transistor 220, a connection manner of the transistor in the semiconductor device may be the same.

Specifically, each of the multiple word lines may be the gate of each of the multiple transistors arranged in parallel along the third direction, and is configured to provide a word line voltage and control the transistor to be turned on or off by the word line voltage. Each of the multiple bit lines is connected to the source or the drain of each of the multiple transistors arranged in parallel along the second direction. Each of the multiple bit lines is configured to perform a read or write operation on each memory cell when each of the multiple transistors is turned on.

In some embodiments, when the source of the transistor is connected to the bit line 403, the drain of the transistor is grounded. When the drain of the transistor is connected to the bit line, the source of the transistor is grounded.

The semiconductor device provided in the embodiment of the disclosure includes various types of memories. For example, it includes NAND flash, Nor Flash, DRAM, Static Random Access Memory (SRAM) and PCM.

In some embodiments, when the semiconductor device is a DRAM, the memory cell further includes a storage capacitor.

FIG. 7C illustrates an optional schematic structural diagram of a DRAM memory cell provided in an embodiment of the disclosure. It may be seen that in the DRAM memory cell, the storage capacitor 404 has one end connected to the drain or the source of the columnar transistor 210 and the other end grounded.

When the transistor includes an inverted T-shaped transistor, the storage capacitor 404 has one end connected to the drain 223 or the source 222 of the inverted T-shaped transistor 220 and the other end grounded.

The storage capacitor 404 is configured to store data written into the memory cell.

In some embodiments, when the semiconductor device is a PCM, the memory cell further includes an adjustable resistor.

FIG. 7D illustrates an optional schematic structural diagram of a PCM memory array provided in an embodiment of the disclosure. It may be seen that in the PCM memory array, an adjustable resistor 405 is connected between the bit line 403 and the source 212 of the columnar transistor 210, or the adjustable resistor 405 is connected between the bit line 403 and the drain 223 of the columnar transistor 220.

When the transistor includes an inverted T-shaped transistor, the adjustable resistor 405 is connected between the bit line 403 and the source 222 of the inverted T-shaped transistor 220, or the adjustable resistor 405 is connected between the bit line 403 and the drain of the inverted T-shaped transistor 220.

The adjustable resistor 405 is configured to adjust a state of data stored in the memory cell by a bit line voltage provided by the bit line. In some embodiments, when the semiconductor device includes multiple memory arrays, the semiconductor device is is a NAND Flash or a Nor Flash. When the multiple memory arrays are connected in parallel, the semiconductor device is a Nor Flash; when the multiple memory arrays are connected in series, the semiconductor device is a NAND Flash.

In some embodiments, when the semiconductor device is a Ferroelectric Random Access Memory (FRAM), the memory cell further includes a ferroelectric capacitor.

The ferroelectric capacitor includes an upper electrode, a lower electrode and a ferroelectric material layer located between the upper electrode and the lower electrode; the upper electrode of the ferroelectric capacitor is connected to the drain of the transistor, the lower electrode of the ferroelectric capacitor is connected to the source of the transistor, and the ferroelectric capacitor is configured to store data written into each of the at least one memory array. Polarity of a ferroelectric material in the ferroelectric material layer may be changed by controlling a voltage difference between the upper electrode and the lower electrode of the ferroelectric capacitor, to store data.

In the embodiments of the disclosure, only some common semiconductor devices are listed as an example, and the protection scope of the disclosure is not limited thereto. Any semiconductor device including at least one of the columnar transistor 210 or the inverted T-shaped transistor 220 provided in the embodiments of the disclosure belongs to the protection scope of the disclosure.

In the embodiments of the disclosure, by designing the structure of the transistor of the semiconductor device as a novel structure with a vertical channel, the area of the memory array is reduced and the storage density of the memory array is improved. Furthermore, the source and the drain of the transistor according to the embodiments of the disclosure are located at the upper and lower ends of the vertical channel region respectively. Thus, during formation of the semiconductor device, the bit line or other structures may be arranged on vertical surfaces of the channel region respectively.

For example, for a DRAM, the bit line and the capacitor of the DRAM memory array may be arranged on two surfaces of the same wafer respectively. In this way, the circuit arrangement of the word line, the bit line and the capacitor may be simplified, difficulty of the process of manufacturing the semiconductor device is reduced.

FIG. 8 is a flowchart of a method for forming a semiconductor device provided in an embodiment of the disclosure. The method may include the following operations.

In operation S501, at least one memory array is formed, here each of at least one memory array includes at least a transistor array including multiple transistors arranged in an array, each of the multiple transistors includes double gates, a source and a drain, and the transistor array is manufactured by the method provided in the embodiments of the disclosure.

In operation S502, multiple word lines arranged in parallel along a third direction are formed, here each of the multiple word lines is connected to the gate of each of the multiple transistors arranged in parallel along the third direction, and is configured to provide a word line voltage and control each of the multiple transistors to be turned on or off by the word line voltage.

In operation S503, multiple bit lines arranged in parallel along a second direction are formed, here each of the multiple bit lines is connected to the source or the drain of each of the multiple transistors arranged in parallel along the second direction, and is configured to perform a read or write operation on each of the at least one memory array when each of the multiple transistors is turned on; the third direction intersects with the second direction, and a plane where the third direction and the second direction are located is perpendicular to a first direction.

For example, each of the at least one memory array includes multiple memory cells arranged in an array. Each of the multiple memory cells includes at least one transistor provided in the embodiments of the disclosure. It should be noted that each of the at least one memory array includes the transistor array provided in the embodiments of the disclosure.

In some embodiments, the columnar transistor 210 in the memory cell is formed by the following operations.

In a first operation, a thickness (corresponding to the first preset thickness in the above embodiments) of silicon is removed from a part of the region of the first surface of the first wafer by an etching process, to form a grid-like trench with silicon pillars in the middle (corresponding to the grid-like etched trench in the above embodiments), the trench is filled with silicon dioxide (corresponding to the insulating layer in the above embodiments), and then the surface of the silicon pillar is exposed by a CMP process, finally a part of silicon dioxide near the silicon pillar is removed by etching, and the first and second sidewalls, opposite to each other in the second direction, of the silicon pillar are exposed (corresponding to the process of forming the transistor pillar in the above embodiments).

In a second operation, silicon nitride is formed at the bottom of the trench to be used as a spacer structure at the bottom (corresponding to the formation of the bottom isolation layer in the above embodiments).

In a third operation, silicon oxide is formed by in-situ growth on the sidewall of the trench to be used as an initial gate oxide layer.

In a fourth operation, the trench is filled with a conductive material (corresponding to the formation of the conductive layer in the above embodiments), and a depth of the conductive material at the top is removed by etching, and then a part of the exposed silicon oxide at the top is removed (corresponding to the formation of the trench 309 in the above embodiments).

In a fifth operation, silicon nitride is formed at the top of the trench to be used as a spacer structure at the top (corresponding to the formation of the isolation layer in the above embodiments).

In a sixth operation, a source is formed in the transistor region reserved in the first operation (corresponding to the first end of the transistor pillar in the above embodiments) by ion implantation.

In a seventh operation, subsequent first corresponding structures are formed on the first surface of the first wafer through various processes, and then the first wafer are bonded to the second wafer, finally silicon on the back surface of the first wafer is thinned until the spacer structure at the bottom and the second surface of the first wafer are exposed (corresponding to the second end of the transistor pillar in the above embodiments).

Here the first corresponding structure includes a structure of forming a bit line, a resistor, or a capacitor, etc. Various elements such as logic circuits and sensors may be arranged in the second wafer. The second wafer may be bonded with the first wafer to form a memory together.

In some embodiments, the process of wafer bonding is implemented before the process of thinning silicon at the back surface, and the second wafer provides support for the first wafer during the thinning process to prevent the first wafer from being damaged during the thinning process.

In an eighth operation, a drain is formed on the second surface of the first wafer, at a position opposite to the source in the sixth operation (corresponding to the second end of the transistor pillar) by ion implantation.

Finally, in a ninth operation, subsequent second corresponding structures are formed on the second surface of the first wafer.

Here the second corresponding structure includes a structure of forming a bit line, a resistor, or a capacitor, etc.

A channel of the columnar transistor 210 formed by using the method for forming a semiconductor device provided in the embodiments of the disclosure is in a vertical direction.

In some embodiments, the inverted T-shaped transistor in the memory cell is formed by the following operations.

In a first operation, a thickness (corresponding to the first preset thickness in the above embodiments) of silicon is removed from a part of the region of the first surface of the first wafer by an etching process, to form a grid-like trench with silicon pillars in the middle (corresponding to the grid-like etched trench in the above embodiments), the trench is filled with silicon dioxide (corresponding to the insulating layer in the above embodiments), and then the surface of the silicon pillar is exposed by a CMP process, finally a part of silicon dioxide near the silicon pillar is removed by etching, to form an exposed L-shaped surface (corresponding to the process of forming the transistor pillar in the above embodiments).

In a second operation, silicon oxide is formed by in-situ growth on the sidewall and the bottom of the trench to be used as an initial gate oxide layer.

In a third operation, the trench is filled with a conductive material (corresponding to the formation of the conductive layer in the above embodiments), and a depth of the conductive material at the top is removed by etching, and then the exposed silicon oxide at the top is removed (corresponding to the formation of the trench 309 in the above embodiments).

In a fourth operation, silicon nitride is formed at the top of the trench to be used as a spacer structure at the top (corresponding to the formation of the second isolation layer in the above embodiments).

In a fifth operation, a source is formed in the transistor region reserved in the first operation (corresponding to the first end of the transistor pillar in the above embodiments) by ion implantation.

In a sixth operation, the first corresponding structures are formed on the first surface of the first wafer through various processes, and then the first wafer are bonded to the second wafer, finally silicon on the back surface of the first wafer is thinned to ensure that a thickness of silicon remains in the region of the trench (corresponding to the etched trench in the above embodiments) and expose the second surface of the first wafer (corresponding to exposing the second end of the transistor pillar in the above embodiments).

In a seventh operation, a drain is formed on the second surface of the first wafer, at a position opposite to the source in the fifth operation (corresponding to the second end of the transistor pillar) by ion implantation.

Finally, in an eighth operation, the second corresponding structures are formed on the second surface of the first wafer.

A channel of the inverted T-shaped transistor formed by using the method for forming a semiconductor device provided in the embodiments of the disclosure is in a T-shaped.

In the semiconductor device formed according to the embodiments of the disclosure, a horizontal cross-section of the transistor may be in a shape of a rectangle (a square), a semicircle, a triangle, or any polygon.

In the semiconductor device formed according to the embodiments of the disclosure, positions of the source and the drain of the transistor may be interchanged, and the source and the drain may be processed on both surfaces of the same wafer respectively.

Therefore, the patterns of the source and the drain may be different.

In the embodiments of the disclosure, the word line and the bit line are implemented by forming conductive lines at a preset word line position and a preset bit line position respectively. Composition material of the conductive line includes but is not limited to wolfram (W), cobalt (Co), copper (Cu), aluminum (Al), polysilicon, doped silicon, silicide, or any combination thereof.

In the embodiments of the disclosure, by designing the structure of the transistor of the semiconductor device as a novel structure with a vertical channel, the area of the memory array is reduced and the storage density of the memory array is improved.

Furthermore, the source and the drain of the transistor according to the embodiments of the disclosure are located at the upper and lower ends of the vertical channel region respectively. Thus, during formation of the semiconductor device, in combination with technologies of wafer bonding and thinning silicon at the back surface, the bit line or other structures may be arranged on opposite surfaces of the wafer respectively. For example, for a DRAM, the bit line and the capacitor of the DRAM memory array may be arranged on two surfaces of the same wafer respectively. In this way, the circuit arrangement of the word line, the bit line and the capacitor may be simplified, difficulty of the process of manufacturing the semiconductor device is reduced.

In several embodiments provided in the disclosure, it should be understood that the disclosed devices and methods may be implemented in a non-target manner. The above device embodiments are merely illustrative. For example, the division of units is only a logical function division, and there may be other divisions in actual implementation, for example, multiple units or components may be combined, or may be integrated into another system, or some features may be ignored or not implemented. In addition, the components as shown or discussed are coupled to each other or directly coupled.

The above units described as separate components may be or may not be physically separate, and the components displayed as units may be or may not be physical units, that is, they may be located at one place or distributed on multiple network units; some or all of the units may be selected according to actual needs to achieve the purpose of the solutions of the embodiments.

The features disclosed in several method or device embodiments provided in the disclosure may be combined arbitrarily without conflict to obtain a new method or device embodiment.

The above are only some implementations of the disclosure, but the protection scope of the disclosure is not limited thereto. Any person skilled in the art may easily conceive of changes or substitutions within the technical scope disclosed in the disclosure, and these changes or substitutions should fall within the protection scope of the disclosure. Therefore, the protection scope of the disclosure shall be subject to the protection scope of the claims.

1. A method for manufacturing a transistor array, comprising:
providing a wafer;
partially etching the wafer from a first surface of the wafer along a first direction, to form a grid-like etched trench and a transistor pillar array, wherein the transistor pillar array comprises a plurality of transistor pillars arranged in an array, each of the plurality of transistor pillars has a first preset thickness smaller than an initial thickness of the wafer, the first direction is a thickness direction of the wafer and is perpendicular to the first surface;
depositing an insulating material in the grid-like etched trench to form an insulating layer surrounding each of the plurality of transistor pillars;
etching the insulating layer to expose a first sidewall and a second sidewall, opposite to each other in a second direction perpendicular to the first direction, of each of the plurality of transistor pillars;
forming a gate oxide layer and a gate sequentially on each of the first sidewall and the second sidewall;
forming a source at a first end of each of the plurality of transistor pillars; and
forming a drain at a second end of each of the plurality of transistor pillars, wherein the first end and the second end are opposite ends of each of the plurality of transistor pillars in the first direction respectively, and a part of each of the plurality of transistor pillars between the source and the drain forms a channel region of the transistor.

2. The method of claim 1, wherein the etching the insulating layer to expose the first sidewall and the second sidewall, opposite to each other in the second direction perpendicular to the first direction, of each of the plurality of transistor pillars comprises:
partially etching the insulating layer along the first direction with positions of a first edge and a second edge, opposite to each other in the second direction, of each of the plurality of transistor pillars as the etching start point, to remove the insulating layer with a preset size in the second direction and with a second preset thickness in the first direction, to form a plurality of etched trenches arranged in parallel along the second direction,
wherein each of the plurality of etched trenches exposes a sidewall of each of the plurality of transistor pillars arranged in parallel along a third direction correspondingly, a plane where the third direction and the second direction are located is perpendicular to the first direction, the third direction intersects with the second direction; the preset size is smaller than an interval between two adjacent transistor pillars in the second direction; and the second preset thickness is smaller than or equal to the first preset thickness.

3. The method of claim 2, wherein the forming the gate oxide layer and the gate sequentially on each of the first sidewall and the second sidewall comprises:
forming, by in-situ oxidation, the gate oxide layer on each of the first sidewall and the second sidewall;
depositing a conductive material in the etched trench formed with the gate oxide layer, to form a conductive layer; and
etching the conductive layer along the first direction, to remove part of the thickness of the conductive layer in the first direction to form the gate.

4. The method of claim 2, wherein the forming the gate oxide layer and the gate sequentially on each of the first sidewall and the second sidewall comprises:
forming, by in-situ oxidation, an initial gate oxide layer on each of the first sidewall and the second sidewall;
depositing a conductive material in the etched trench formed with the initial gate oxide layer, to form a conductive layer; and
etching the initial gate oxide layer and the conductive layer along the first direction, to remove part of the thicknesses of the initial gate oxide layer and the conductive layer in the first direction to form the gate.

5. The method of claim 2, further comprising after forming the gate oxide layer and the gate:
forming an isolation layer by deposition in the etched trench, wherein a size of the isolation layer in the third direction is larger than a size of each of the plurality of transistor pillars in the third direction.

6. The method of claim 1, further comprising before forming the drain:
thinning the wafer from a second surface of the wafer until exposing the second end of each of the plurality of transistor pillars, wherein the second surface of the wafer is a surface opposite to the first surface of the wafer.

7. The method of claim 1, wherein cross-sectional shapes of the source and the drain parallel to a preset plane are the same or different, and the preset plane is perpendicular to the first direction; and
the cross-sectional shapes of the source and the drain parallel to the preset plane comprise any one of a square, a semicircle, a triangle, or any polygon.

8. The method of claim 1, wherein
each of the plurality of transistor pillars is a columnar transistor pillar, and a length of each of the first sidewall and the second sidewall in the first direction is smaller than the first preset thickness.

9. The method of claim 1, wherein
each of the plurality of transistor pillars is an inverted T-shaped transistor pillar, and a length of each of the first sidewall and the second sidewall in the first direction is equal to the first preset thickness.

10. A transistor array, comprising a plurality of transistors arranged in an array, each of the plurality of transistors comprising:
a channel region;
a source located at a first end of the channel region;
a drain located at a second end of the channel region, wherein the first end and the second end are opposite ends of the channel region in a first direction which is a thickness direction of a wafer forming the channel region;
double gates located on two sides of the channel region respectively, each of the double gates corresponding to the channel region;
a gate oxide layer located between the channel region and each of the double gates; and
an isolation layer arranged on each of the double gates along the first direction and extending along a third direction, wherein a size of the isolation layer in the third direction is greater than a size of the channel region in the third direction, and the third direction is parallel to a column arrangement direction of the transistor array.

11. A method for forming a semiconductor device, comprising:
forming at least one memory array, each of which comprising at least a transistor array comprising a plurality of transistors arranged in an array, each of the plurality of transistors comprising double gates, a source and a drain, and the transistor array being manufactured by the method of claim 1;
forming a plurality of word lines arranged in parallel along a third direction, each of the plurality of word lines connected to the double gates of each of the plurality of transistors arranged in parallel along the third direction, and configured to provide a word line voltage and control each of the plurality of transistors to be turned on or off by the word line voltage; and
forming a plurality of bit lines arranged in parallel along a second direction, each of the plurality of bit lines connected to the source or the drain of each of the plurality of transistors arranged in parallel along the second direction, and configured to perform a read or write operation on each of the plurality of transistors when each of the plurality of transistors is turned on, the third direction intersects with the second direction, and a plane where the third direction and the second direction are located is perpendicular to the first direction.

12. A semiconductor device, comprising:
at least one memory array, a plurality of word lines arranged in parallel along a third direction, and a plurality of bit lines arranged in parallel along a second direction;
wherein each of the at least one memory array comprises the transistor array of claim 10, each of the plurality of transistors comprises at least double gates, a source and a drain; and the third direction intersects with the second direction, and a plane where the third direction and the second direction are located is perpendicular to the first direction;
each of the plurality of word lines is connected to the double gates of each of the plurality of transistors arranged in parallel along the third direction, and is configured to provide a word line voltage and control each of the plurality of transistors to be turned on or off by the word line voltage; and
each of the plurality of bit lines is connected to the source or the drain of each of the plurality of transistors arranged in parallel along the second direction, and is configured to perform a read or write operation on each of the at least one memory array when each of the plurality of transistors is turned on.

13. The semiconductor device of claim 12, wherein each of the at least one memory array further comprises a storage capacitor,
the storage capacitor has one end connected to the drain or the source of the transistor and the other end grounded, and is configured to store data written into each of the at least one memory array.

14. The semiconductor device of claim 12, wherein each of the at least one memory array further comprises a ferroelectric capacitor,
the ferroelectric capacitor comprises an upper electrode, a lower electrode and a ferroelectric material layer located between the upper electrode and the lower electrode; the upper electrode of the ferroelectric capacitor is connected to the drain of the transistor, and the lower electrode of the ferroelectric capacitor is connected to the source of the transistor, and the ferroelectric capacitor is configured to store data written into each of the at least one memory array.

15. The semiconductor device of claim 12, wherein each of the at least one memory array further comprises an adjustable resistor,
the adjustable resistor is connected between the bit line and the source of the transistor, or is connected between the bit line and the drain of the transistor, and is configured to adjust a state of data stored in each of the at least one memory array by a bit line voltage provided by the bit line.

16. The semiconductor device of claim 12, when the semiconductor device comprises a plurality of memory arrays, the plurality of memory arrays are connected in parallel or in series.
